(19) United States
(12) Patent Application Publication
(10) Pub. No.: US 2008/0309379 A1
(43) Pub. Date: Dec. 18, 2008

(54) Zero crossing circuit

(76) Inventor: Sean C. Carroll, Kelowna (CA)

Correspondence Address: Antony C. Edwards, P.O. Box 26020, Westbank, BC, V4T 2G3, CA

(21) Appl. No.: 12/073,109

(22) Filed: Feb. 29, 2008

Related U.S. Application Data
(60) Provisional application No. 60/904,387, filed on Mar. 2, 2007.

(51) Int. Cl. H03K 5/153

(52) U.S. Cl. 327/79

(57) ABSTRACT

An improved zero crossing circuit includes a signal output circuit element for registering a sharply defined signal, and in one embodiment an isolation circuit element cooperating with the signal output element, and a delay-inducing circuit element cooperating with the signal output element for applying a substantially constant time delay to the signal. In particular, the delay-inducing element includes a switch circuit and a delay circuit. The switch circuit commences the time delay by the delay circuit upon a triggering voltage being reached. The time delay circuit is adapted so that the time delay equates to a time period required for the triggering voltage to change to zero so as to cross zero voltage substantially as the time delay expires.

### CROSS REFERENCE TO RELATED APPLICATION

This application claims priority from United States Provisional Patent Application No. US Provisional Application No. 60/904,387 filed Mar. 2, 2007 entitled Zero-Crossing Detector.

### FIELD OF THE INVENTION

The invention relates to the field of devices for detecting a zero-crossing voltage of an alternating current signal, and in particular to such a device wherein a delay inducing circuit element causes a trigger signal upon the voltage dropping to a predetermined level thereby signalling the zero crossing as the voltage coincides with the actual zero

### BACKGROUND OF THE INVENTION

Zero crossing is a commonly used term in electronics. In alternating current, the zero crossing is the instantaneous point at which there is no voltage present. This occurs twice during each cycle. Zero crossing detectors are used to detect the zero cross in solid state relays. The purpose of the circuit is to turn on the solid state relay as close to the zero crossing as possible. Zero crossing detectors are also used in systems to coordinate operation. Devices plugged into the AC power can keep track of the zero crossing to perform various timing dependant operations as each device sees the same AC power. For these and other reasons zero cross detector circuits have important applications.

Nakata et al. in U.S. Pat. No. 6,664,817 which issued Dec. 16, 2003, entitled Zero-Cross Detection Circuit discloses a power supply device including a full-wave rectifying and smoothing circuit powered from a commercial AC power supply via two power supply lines, a switching regulator for separating and stepping down the output from the full-wave rectifying and smoothing circuit to output a desired DC voltage, and two capacitors after the full-wave rectifying and smoothing circuit for the terminal noise suppression purpose, a zero-cross detection circuit includes a transistor of which the emitter is connected to the low-voltage output terminal of the full-wave rectifying and smoothing circuit for outputting a zero-cross detection signal from the collector; a first resistor is connected between the base and emitter of the transistor; a second resistor is connected between one of the power supply lines and the base of the transistor; and a third resistor is connected between the other power supply line and the emitter of the transistor.

Gottshall et al. in U.S. Pat. No. 5,606,273 which issued Feb. 25, 1997, entitled Zero Crossing Detector Circuit discloses in one aspect a zero crossing detecting circuit. The circuit includes a first comparator having an inverting and non-inverting input connected to an input signal. The non-inverting input of the first comparator is further connected to the first comparator output to provide a feed forward path. A second comparator is additionally included having an output connected to the first comparator inverting input. This provides the inverting input of the first comparator with a reference voltage that is substantially equal to that of the first comparator non-inverting input; thereby, providing the first comparator with balanced inputs.

Hoekman in U.S. Pat. No. 5,239,209 which issued Aug. 24, 1993, entitled Zero Crossing Detection Circuit discloses a zero crossing detection circuit which produces an output signal which changes state to indicate the occurrence of a positive-going zero crossing of an AC input signal. The circuit includes first and second input terminals, a current sensitive switch such as an opto-isolator, first and second current regulators, and a voltage limiter. The first current regulator is connected in series with the current sensitive switch, and the voltage limiter is connected in parallel with the first current regulator and the current sensitive switch. The second current regulator is connected between the first input terminal and the parallel combination of the voltage limiter and the first current regulator and the current sensitive switch. The first current regulator limits current through the current sensitive switch to a first current limit level, and the second current regulator limits current flowing between the first and second input terminals to a second current limit level which is greater than the first current level. The zero crossing detection circuit offers the ability to sense zero crossings of AC input signals having a wide range of AC voltages.

### SUMMARY OF THE INVENTION

In summary, the improved zero crossing circuit according to one aspect of the present invention may be characterized as a circuit for detecting a zero-crossing voltage in an alternating current signal wherein the circuit may include a signal outputting means for registering a sharp-edged definitive signal having a magnitude sufficient to be readily detectable, and an isolation means cooperating with the signal outputting means, and wherein the improvement includes a delay-inducing means cooperating with the signal outputting means for applying a substantially constant time delay to the signal. In particular, the delay-inducing means includes a switch circuit and a delay circuit. The switch circuit commences the time delay by the delay circuit upon a triggering voltage being reached. The time delay circuit is adapted so that the time delay equates to a time period required for the triggering voltage to change to zero so as to cross zero voltage substantially as the time delay expires.

In one embodiment the switch circuit includes at least one transistor and the delay circuit includes at least one capacitor, and wherein the at least one transistor and the at least one capacitor are mounted in parallel between a line voltage and a neutral line. The at least one transistor may be single transistor, and the at least one capacitor may be a single capacitor. At least one resistor may be advantageously mounted in series with a corresponding at least one transistor. The signal outputting means may be a thysistor, or other avalanche means, and the isolation means may be an opto-coupler.

In the above circuit a method according to another aspect of the present invention for detecting a zero-crossing voltage in an alternating current signal includes the steps of:
(a) adapting the switch circuit to cooperate with the delay circuit so as to commence the time delay upon the voltage reaching the triggering voltage and so as to thereby delay a sharp-edged definitive signal by the time delay,
(b) commencing the time delay upon the voltage reaching the triggering voltage,
(c) delaying the signal by the time delay,
(d) adapting the time delay so that it is substantially constant and expires at a time substantially equating to when the voltage crosses a zero voltage in the alternating current signal,
(e) generating the signal after the time delay and substantially simultaneously with the voltage crossing the zero voltage.

### BRIEF DESCRIPTION OF THE DRAWINGS

With reference to the drawings wherein similar characters of reference denote corresponding parts in each view:

FIG. 1 illustrates, in a first trace, the sinusoidal rise and fall of a voltage in an alternating current, and in a second trace the output of a device registering the zero crossing of the voltage.

FIG. 2a is a prior art circuit containing a thyristor-like trigger and an optocoupler.

FIG. 2b is a prior art variant of the circuit of FIG. 2a.

FIG. 2c is a prior art variant of the circuit of FIG. 2a showing the optocoupler removed.

FIG. 3 is a trace of the sinusoidal rise and fall of voltage in an alternating current illustrating a brief, downward voltage spike momentarily pulling down the voltage trace from approximately positive 50 volts to negative 50 volts prior to the sinusoidal voltage trace dropping to its zero crossing.

FIG. 4 is, in a first trace, the voltage trace of FIG. 3, and its second trace, the output of a device for detecting zero crossings showing zero crossings registering due to both the downward voltage spike and the actual zero crossing of the sinusoidal voltage trace.

FIG. 5 is a prior art circuit illustrating the use of a capacitor C2 before the trigger element T.

FIG. 6 is a circuit according to one embodiment of the present invention showing within circuit element S one embodiment of the delay-inducing means according to the present invention.

FIG. 6a is a sinusoidal voltage trace diagrammatically illustrating the time delay D resultant of the operation of circuit element S in FIG. 6.

FIG. 7 illustrates, in a first trace, a voltage trace similar to that of FIG. 3 including a similar voltage spike, and in a second trace, illustrates the output of a device for detecting zero crossings which, employing the present invention, shows an output registering only the actual zero crossing of the sinusoidal voltage trace.

FIG. 8 is a further embodiment of the improved circuit according to the present invention, being a variant of the circuit of FIG. 6.

FIG. 9 is a further variant of the circuit of FIG. 6 showing the optocoupler removed.

### DETAILED DESCRIPTION OF EMBODIMENTS OF THE INVENTION

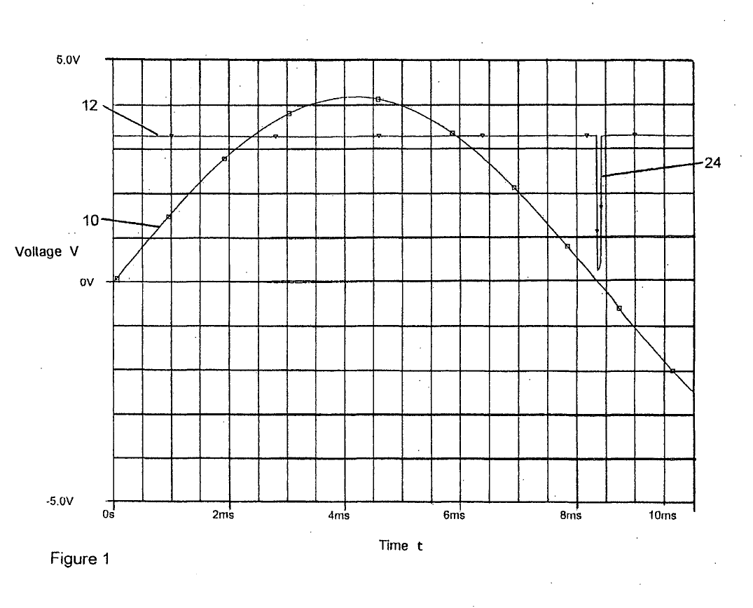

Many systems take advantage of AC line voltage to help synchronize transmissions of data and other timing details. An example would be a number of small RF devices that are all being powered from the AC line and wish to synchronize their transmissions to avoid transmission collisions. An effective method for monitoring the AC line is to use a zero crossing detector. The zero crossing detector triggers when the line voltage transitions from positive to negative (or vise versa) with respect to neutral. FIG. 1 shows this.

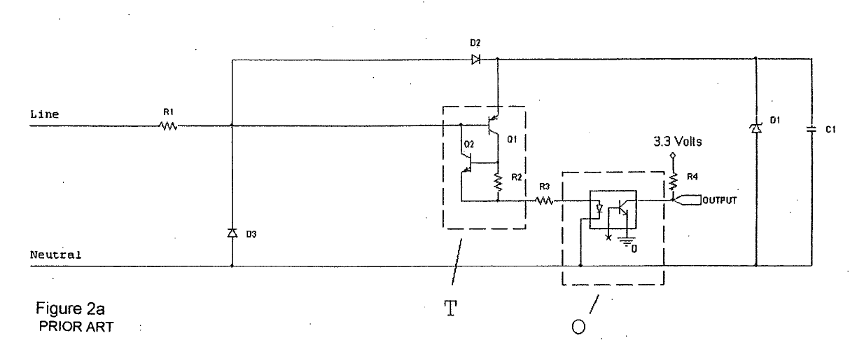

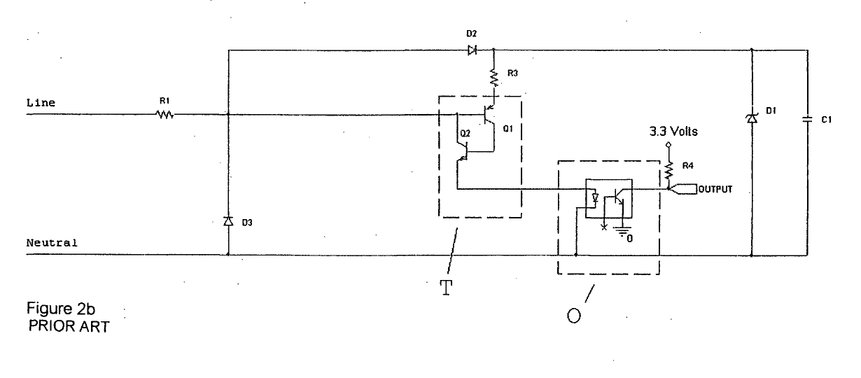

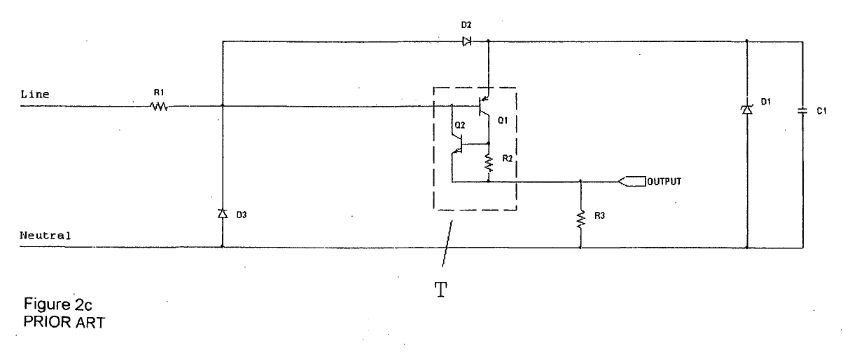

The first trace 10 of FIG. 1 is the line to neutral voltage scaled by dividing it by 40. The second trace 12 shows the output of the zero crossing circuit shown in FIG. 2a. As can be seen the output 24 pulses low at the negative-going zero crossing of the line voltage. The 3.3 volts of the second trace 12 comes from a power supply that powers a microprocessor or the equivalent.

The circuits of FIG. 2a work as follows: Assuming that the line voltage is lower than neutral and capacitor C1 is discharged a small amount of current flows though diode D3 and resistor R1. As used herein, the letters C, D, R and Q refer to capacitors, diodes, resistors and transistors respectively. When the line voltage becomes positive current starts to flow through R1 and D2 and begins charging C1. Zener diode D1 clamps the voltage across C1, VC1, at a reasonable level. When the line voltage drops below VC1 diode D2 becomes reverse biased and VC1 stays essentially constant for the brief period before the circuit triggers. When the line voltage falls sufficiently below VC1 for transistor Q1 to start conduction the triggered element T is triggered. Q1 and Q2 form the functional equivalent of a thyristor or SCR or other avalanche-type device as is well known in the art. When triggered element T is triggered, current flows from C1 through T, R3 and the light emitting diode in the optocoupler O. This causes the optotransistor in optocoupler O to conduct thereby pulling the output low. The output in this figure is normally pulled high by resistor R4 and a 3.3 Volt supply. As will be understood by those skilled in the art the voltage need not be 3.3 Volts as indicated. As well optocoupler O could be used to pull the output high briefly and could be a different form of optocoupler, etc. It is also possible to use a pulse transformer in place of an optical isolation means such as an optocoupler. The circuit element symbolized by optocoupler O is meant to include other means of isolation and is thus not intended to be limiting. Resistor R2 reduces the sensitivity of triggered element T and may or may not be present. Resistor R3 is used to limit the current flowing from C1.

FIG. 2b shows a variation of the circuit of FIG. 2a, wherein R3 is placed before the trigger element T and R2 is absent.

As mentioned above the voltage of 3.3 Volts need not be used and the optocoupler need not be the same or used in the same way as indicated in FIGS. 2a and 2b. In fact the circuit can be used in a non-isolated manner where the output is taken directly off R3 as shown in FIG. 2c. Here the output will pulse high when triggered element T is triggered.

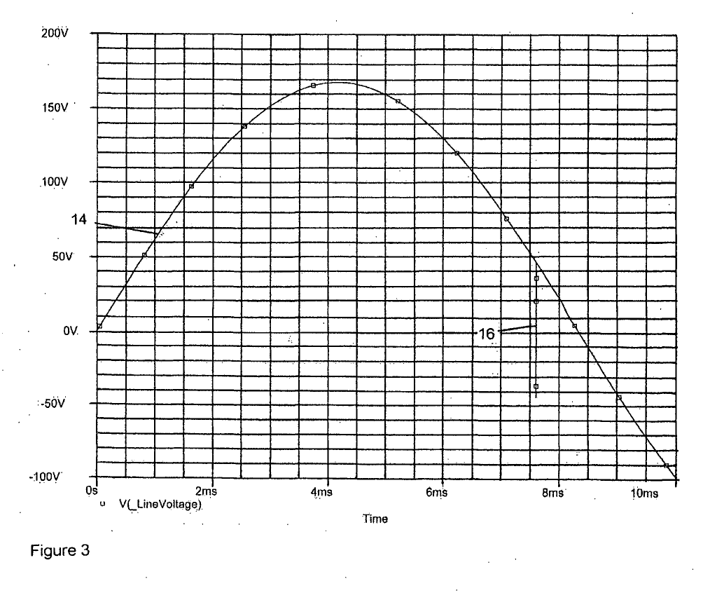

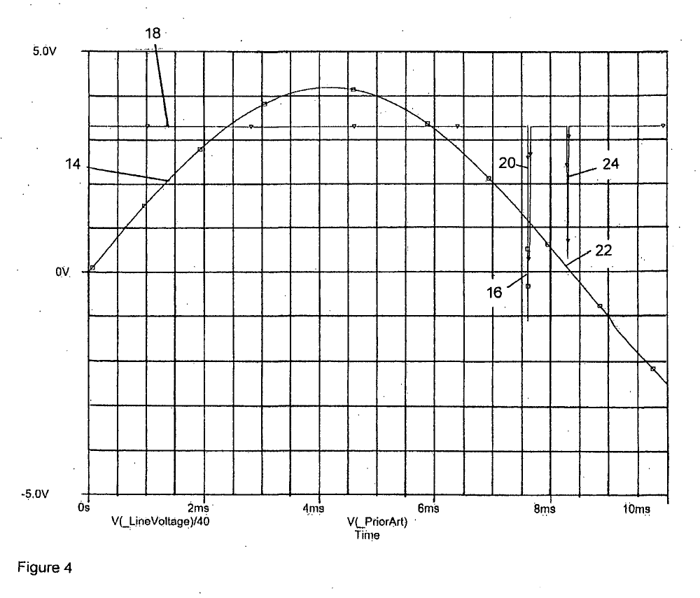

The problem with the circuit of FIGS. 2a -2c is that the circuit is susceptible to false triggering due to line noise, especially voltage spikes. Since the entire purpose of the circuit is to trigger a sharp definitive detectable output such as output 24, especially at the leading edge of the output at the zero crossing, false triggering is to be avoided. FIG. 3 shows line to neutral voltage 14 with a voltage spike 16 scaled by dividing it by 40. FIG. 4 shows in the second trace 18 the output of the circuit of FIG. 2a false triggering output 20 which is not at the zero crossing 22 due to the voltage spike 16 of FIG. 3.

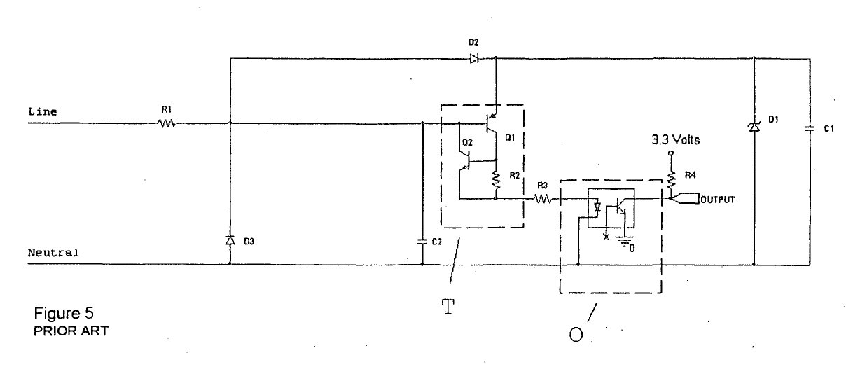

It is possible and known to filter voltage spikes with the addition of some capacitance C2 after resistor R1 of FIG. 2. FIG. 5 shows this. This is not an optimal solution however because for C2 to be effective at preventing false triggering it will cause a time lag that makes the circuit trigger significantly later than the zero crossing. As well, this time lag is sensitive to temperature. That is, the circuit's output moves substantially with respect to the zero crossing as its operating temperature changes. This makes the time lag variable and thus difficult to compensate for in software and not as useful for timing of devices, data, etc.

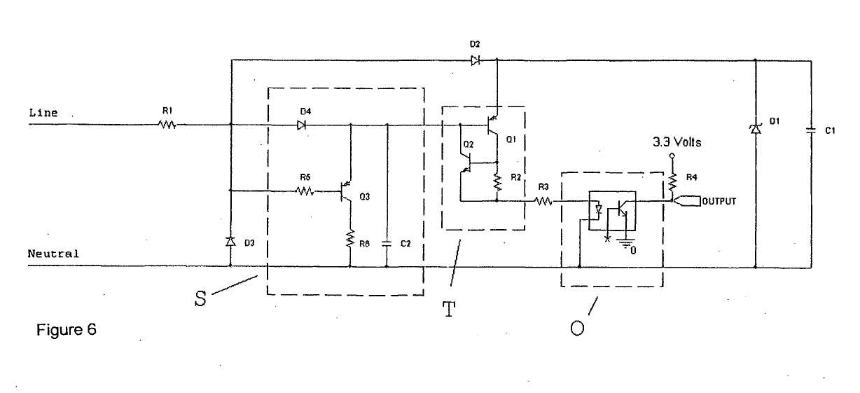

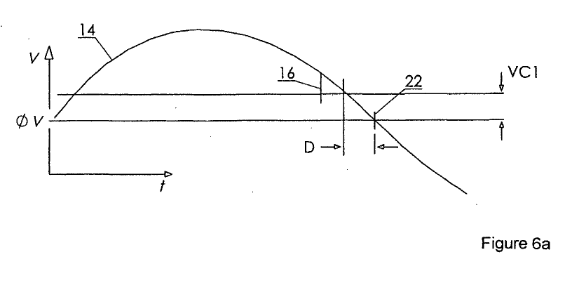

FIG. 6 shows an improved circuit according to one embodiment of the present invention wherein diode D4, resistors R5, R6 and transistor Q3 have been added to the circuit of FIG. 5. These components in combination with capacitor C2 form in essence a switch, shown for ease of identification within a box S, that, in cooperation with the rest of the circuit, has a substantially constant time delay D, as shown diagrammatically in FIG. 6a, that prevents the voltage spikes from causing false triggering. That is, if the switch is turned on for a brief time and then turned off, as would happen in the case of a voltage spike 16 such as shown in FIG. 3, the circuit does not trigger a false output 20 such as seen in FIG. 4.

Rather, the false output 20 on the second trace 18 is avoided so long as the spike 16 is short enough in duration that is the spike is not seen as it has a duration less than the substantially constant time delay D. As seen in FIG. 6a, time delay D corresponds to the time it takes the voltage of the power line to fall by the amount of VC1. By way of example, not intended to be limiting, a realistic voltage spike 16 may have a duration in the order of 10 microseconds, so a time delay provided by the switch elements of the circuit in the order of at least slightly greater than 10 microseconds, or some multiple thereof (10-30 microseconds for example), would be advantageous. The values of the components can be chosen so that during a true zero crossing the circuit produces an output without a time lag. As well the circuit of FIG. 6 is much less temperature sensitive than the circuit shown in FIG. 5.

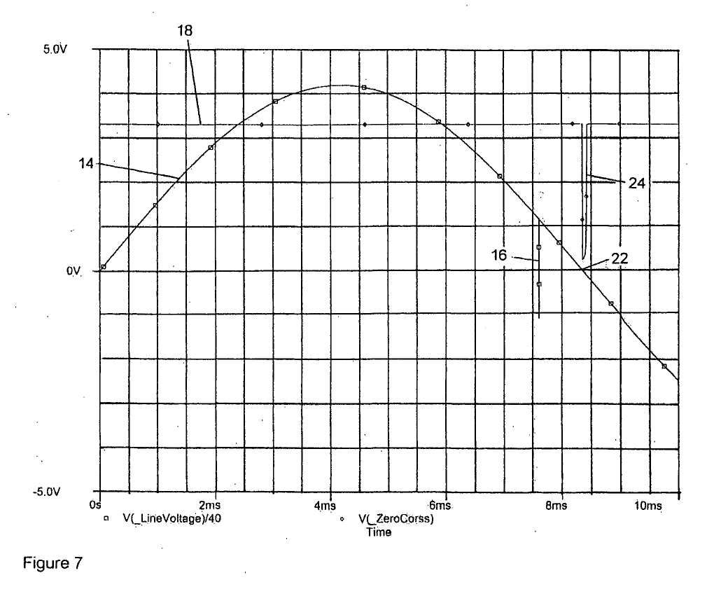

FIG. 7 shows the output of the improved circuit of FIG. 6 with the same voltage spike 16 as shown in FIGS. 3 and 4. As can be seen the circuit does not falsely trigger, and it produces an output 24 at the zero crossing 22. As may be seen, advantageously output 24 is a sharp-edged definitive signal having a magnitude sufficient to be readily detectable, such as would be produced by a thyristor-like device such as in triggered element T. In fact this circuit will not falsely trigger even for much larger voltage spikes.

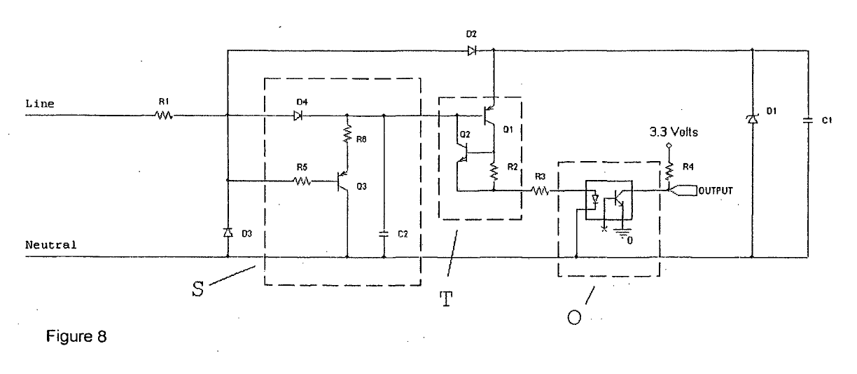

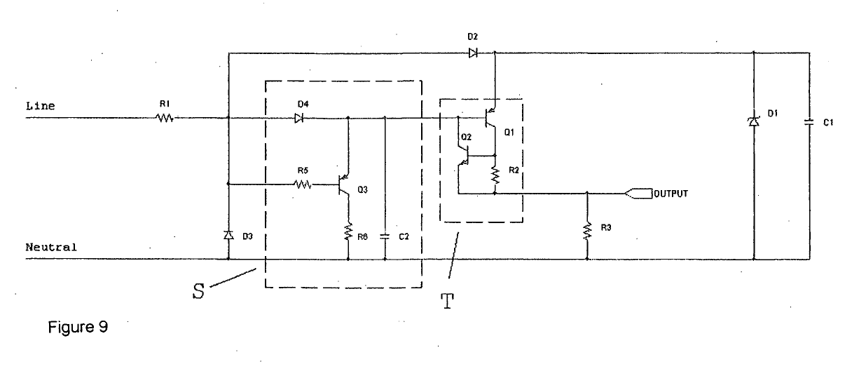

FIG. 8 shows a further embodiment of the improved circuit according to the present invention, which is a variation of the circuit of FIG. 6. FIG. 9 shows a non-isolated version of the improved circuit on FIG. 6.

By way of example, not intending to be limiting, the components inside box S of FIG. 6 may have the following values/descriptions.

| | |
|---|---|
| R5 | 470 kiloOhms |
| R6 | 39 kiloOhms |
| C2 | 30 nanoFarads |
| D4 | 1N4148 |
| Q3 | 2N3906 |

These components would cooperate with D1 and C1 to produce an output substantially at the zero crossing for 120 VAC for D1, C1 having the following values/descriptions:

| | |
|---|---|
| D1 | BZXC10 (10 Volt Zener diode) |
| C1 | 30 nanoFarads |

Although the previous discussion has focused on the synchronization of systems, the circuit has other uses. Often zero cross detectors are used to switch loads at the zero crossing so as to minimize the in-rush of current to a load and/or inductive kicks from a load. Since the improved circuit of the present invention will not false trigger and will trigger at the zero cross it has applications for these devices as well.

As will be apparent to those skilled in the art in the light of the foregoing disclosure, many alterations and modifications are possible in the practice of this invention without departing from the spirit or scope thereof. Accordingly, the scope of the invention is to be construed in accordance with the substance defined by the following claims.

What is claimed is:

1. A circuit for detecting a zero-crossing voltage in an alternating current signal wherein the circuit includes a signal outputting means for outputting a sharp-edged definitive signal having a magnitude sufficient to be readily detectable, and may include an isolation means cooperating with the signal outputting means, wherein the improvement comprises a delay-inducing means cooperating with the signal outputting means for applying a substantially constant time delay to said sharp-edged definitive signal, said delay-inducing means comprising a switch circuit and a delay circuit, said switch circuit for commencing said time delay by said delay circuit upon a triggering voltage being reached, and wherein said time delay circuit is adapted so that said time delay equates to a time period required for said triggering voltage to change to zero so as to cross zero voltage substantially as said time delay expires.

2. The circuit of claim 1 wherein said switch circuit includes at least one transistor and said delay circuit includes at least one capacitor, and wherein said at least one transistor and said at least one capacitor are mounted in parallel between a line voltage and a neutral line.

3. The circuit of claim 2 wherein said at least one transistor is a single transistor.

4. The circuit of claim 2 wherein said at least one capacitor is a single capacitor.

5. The circuit of claim 2 wherein said at least one capacitor and said at least one transistor are, respectively, a single capacitor and a single resistor.

6. The circuit of claim 2 wherein at least one resistor is mounted in series with said at least one transistor.

7. The circuit of claim 3 wherein a resistor is mounted in series with said single transistor.

8. The circuit of claim 2 wherein said signal outputting means is a signal avalanche device for generating a sharp-edged signal.

9. The circuit of claim 8 wherein said signal avalanche device is a thyristor means.

10. A circuit for detecting a zero-crossing voltage in an alternating current signal wherein the improvement comprises a delay-inducing means for applying a substantially constant time delay to a sharp-edged definitive signal having a magnitude sufficient to be readily detectable, said delay-inducing means comprising a switch circuit and a delay circuit, said switch circuit for commencing said time delay by said delay circuit upon a triggering voltage being reached, and wherein said time delay circuit is adapted so that said time delay equates to a time period required for said triggering voltage to change to zero so as to cross zero voltage substantially as said time delay expires.

11. The circuit of claim 11 wherein said switch circuit includes at least one transistor and said delay circuit includes at least one capacitor, and wherein said at least one transistor and said at least one capacitor are mounted in parallel between a line voltage and a neutral line.

12. The circuit of claim 11 wherein said at least one transistor is a single transistor.

13. The circuit of claim 11 wherein said at least one capacitor is a single capacitor.

14. The circuit of claim 11 wherein said at least one capacitor and said at least one transistor are, respectively, a single capacitor and a single resistor.

15. The circuit of claim 12 wherein at least one resistor is mounted in series with said at least one transistor.

16. The circuit of claim 3 wherein a resistor is mounted in series with said single transistor.

17. In a circuit for detecting a zero-crossing voltage in an alternating current signal, wherein the circuit includes a signal outputting means for outputting a sharp-edged definitive signal having a magnitude sufficient to be readily detectable, and may include an isolation means cooperating with the signal outputting means, and wherein a delay-inducing means cooperates with the signal outputting means for applying a delay-inducing means for applying a substantially constant time delay to said signal, and wherein said delay-inducing means includes a switch circuit and a delay circuit, said switch circuit for commencing said time delay by said delay circuit upon a triggering voltage being reached, and wherein said time delay circuit is adapted so that said time delay equates to a time period required for said triggering voltage to change to zero so as to cross zero voltage substantially as said time delay expires, a method of detecting a zero-crossing voltage in an alternating current signal comprising the steps of:
(a) adapting said switch circuit to cooperate with said delay circuit so as to commence said time delay upon the voltage reaching said triggering voltage and so as to thereby delay said signal by said time delay,
(b) commencing said time delay upon said voltage reaching said triggering voltage,
(c) delaying said signal by said time delay,
(d) adapting said time delay so that it is substantially constant and expires at a time substantially equating to when said voltage crosses a zero voltage in said alternating current signal,
(e) generating said signal after said time delay and substantially simultaneously with said voltage crossing said zero voltage.

18. In a circuit for detecting a zero-crossing voltage in an alternating current signal, wherein a delay-inducing means applies a substantially constant time delay to a sharp-edged definitive signal having a magnitude sufficient to be readily detectable, and wherein said delay-inducing means includes a switch circuit and a delay circuit, said switch circuit for commencing said time delay by said delay circuit upon a triggering voltage being reached, and wherein said time delay circuit is adapted so that said time delay equates to a time period required for said triggering voltage to change to zero so as to cross zero voltage substantially as said time delay expires, a method of detecting a zero-crossing voltage in an alternating current signal comprising the steps of:
(a) adapting said switch circuit to cooperate with said delay circuit so as to commence said time delay upon the voltage reaching said triggering voltage and so as to thereby delay said signal by said time delay,
(b) commencing said time delay upon said voltage reaching said triggering voltage,
(c) delaying said signal by said time delay,
(d) adapting said time delay so that it is substantially constant and expires at a time substantially equating to when said voltage crosses a zero voltage in said alternating current signal,
(e) generating said signal after said time delay and substantially simultaneously with said voltage crossing said zero voltage.
